(19) United States
(12) Patent Application Publication
(10) Pub. No.: US 2022/0238711 A1
(43) Pub. Date: Jul. 28, 2022

(54) SEMICONDUCTOR DEVICE HAVING MOS TRANSISTOR FOR EFFICIENT STRESS TRANSFER

(71) Applicant: MICRON TECHNOLOGY, INC., BOISE, ID (US)

(72) Inventor: Takuya Imamoto, Higashihiroshima (JP)

(73) Assignee: MICRON TECHNOLOGY, INC., BOISE, ID (US)

(21) Appl. No.: 17/160,038

(22) Filed: Jan. 27, 2021

(51) Int. Cl. H01L 29/78; H01L 29/66; H01L 29/06; H01L 29/423; H01L 27/088; H01L 21/38; H01L 21/8234

(52) U.S. Cl. CPC H01L 29/7833; H01L 29/6659; H01L 29/0649; H01L 21/823412; H01L 27/088; H01L 21/38; H01L 29/42364

(57) ABSTRACT

Disclosed herein is a method that includes forming a gate electrode on an active region of a semiconductor substrate surrounded by a STI region; implanting a first dopant into the active region by using the gate electrode as a mask to form LDD regions; forming a liner film on top and side surfaces of the gate electrode, the STI region, and the LDD regions; forming a side wall spacer on the side surfaces of the gate electrode with the liner film interposed therebetween; implanting, with covering the STI region and the LDD regions by the liner film, a second dopant by using the gate electrode, the liner film formed on the side surfaces of the gate electrode, and the side wall spacer as a mask to form source/drain regions; and removing the side wall spacer.

### BACKGROUND

A method of applying physical stress to a channel region to increase the carrier mobility is known as a method for increasing the switching rate of a MOS transistor. Examples of the method of applying physical stress to a channel region include a method of covering a MOS transistor with a contact etch stop liner (CESL) and a method of embedding an epitaxial layer in source/drain regions. These methods are effective in a case where the interval between the gate electrodes of adjacent MOS transistors is sufficiently wide. However, when the distance between the gate electrodes of adjacent MOS transistors is narrow, these methods have a problem where less physical stress is applied to the channel region and the carrier mobility is not sufficiently increased.

### BRIEF DESCRIPTION OF THE DRAWINGS

FIG. 1 is a block diagram of a semiconductor device according to the present disclosure;

FIG. 2 is a schematic plan view of a MOS transistor,

FIG. 3A is a schematic cross-section along a line A-B shown in FIG. 2, and shows a configuration of a MOS transistor constituting a peripheral device;

FIG. 3B is a schematic cross-section along a line A-B shown in FIG. 2, and shows a configuration of a MOS transistor constituting a pitch device;

FIGS. 4 to 9 are process diagrams for explaining a manufacturing process of the semiconductor device according to the present disclosure, and show a manufacturing process common to the MOS transistor constituting a peripheral device and a MOS transistor constituting a pitch device;

FIG. 10A is a process diagram for explaining a manufacturing process of the semiconductor device according to the present disclosure, and a manufacturing process of the MOS transistor constituting a peripheral device;

FIG. 10B is a process diagram for explaining a manufacturing process of the semiconductor device according to the present disclosure, and a manufacturing process of the MOS transistor constituting a pitch device;

FIG. 11A is a process diagram for explaining a manufacturing process of the semiconductor device according to the present disclosure, and a manufacturing process of the MOS transistor constituting a peripheral device;

FIG. 11B is a process diagram for explaining a manufacturing process of the semiconductor device according to the present disclosure, and a manufacturing process of the MOS transistor constituting a pitch device;

FIG. 12A is a process diagram for explaining a manufacturing process of the semiconductor device according to the present disclosure, and a manufacturing process of the MOS transistor constituting a peripheral device;

FIG. 12B is a process diagram for explaining a manufacturing process of the semiconductor device according to the present disclosure, and a manufacturing process of the MOS transistor constituting a pitch device;

FIG. 13A is a process diagram for explaining a manufacturing process of the semiconductor device according to the present disclosure, and a manufacturing process of the MOS transistor constituting a peripheral device;

FIG. 13B is a process diagram for explaining a manufacturing process of the semiconductor device according to the present disclosure, and a manufacturing process of the MOS transistor constituting a pitch device;

FIG. 14A is a process diagram for explaining a manufacturing process of the semiconductor device according to the present disclosure, and a manufacturing process of the MOS transistor constituting a peripheral device;

FIG. 14B is a process diagram for explaining a manufacturing process of the semiconductor device according to the present disclosure, and a manufacturing process of the MOS transistor constituting a pitch device;

FIG. 15A is a process diagram for explaining a manufacturing process of the semiconductor device according to the present disclosure, and a manufacturing process of the MOS transistor constituting a peripheral device;

FIG. 15B is a process diagram for explaining a manufacturing process of the semiconductor device according to the present disclosure, and a manufacturing process of the MOS transistor constituting a pitch device;

FIG. 16A is a process diagram for explaining a manufacturing process of the semiconductor device according to the present disclosure, and a manufacturing process of the MOS transistor constituting a peripheral device; and

FIG. 16B is a process diagram for explaining a manufacturing process of the semiconductor device according to the present disclosure, and a manufacturing process of the MOS transistor constituting a pitch device.

### DETAILED DESCRIPTION

Various embodiments of the present invention will be explained below in detail with reference to the accompanying drawings. The following detailed description refers to the accompanying drawings that show, by way of illustration, specific aspects, and embodiments in which the present invention may be practiced. These embodiments are described in sufficient detail to enable those skilled in the art to practice the present invention. Other embodiments may be utilized, and structural, logical, and electrical changes may be made without departing from the scope of the present invention. The various embodiments disclosed herein are not necessary mutually exclusive, as some disclosed embodiments can be combined with one or more other disclosed embodiments to form new embodiments.

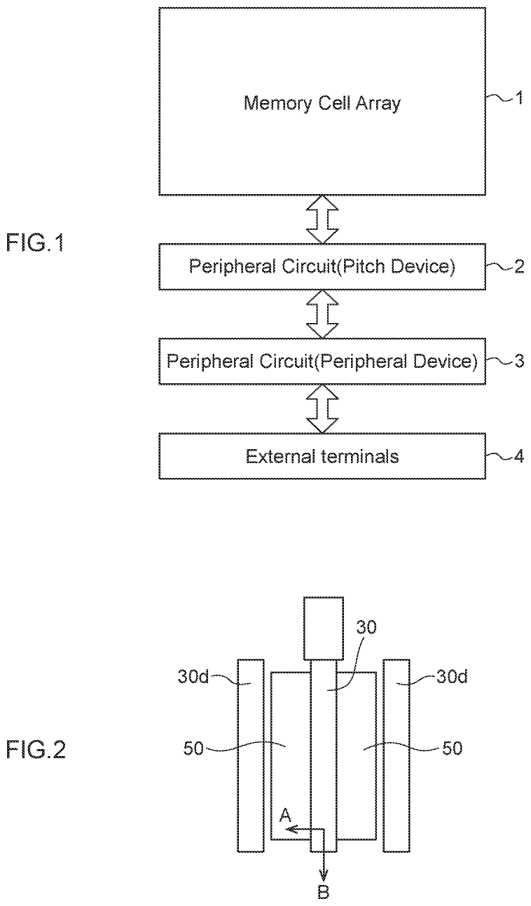

A semiconductor device shown in FIG. 1 is, for example, a DRAM (Dynamic Random Access Memory) and includes a memory cell army 1 including a plurality of memory cells, a peripheral circuit (pitch device) 2 connected to the memory cell army 1, a peripheral circuit (peripheral device) 3 connected to the peripheral circuit (pitch device) 2, and external terminals 4 connected to the peripheral device 3. The pitch device 2 is a circuit directly connected to the memory cell array 1 and includes a sense amplifier, a bit line equalizer, a column switch, a sub-word driver, a pull-up circuit for a local I/O line, an activation circuit for the sense amplifier, and the like. The peripheral device 3 is other peripheral circuits included in the semiconductor device and includes a decoder, a counter, a clock control circuit, a FIFO (First-In First-Out) circuit, an input/output circuit, and the like. The memory cells in the memory cell array 1 are arranged in a smallest pitch. Since the pitch device 2 is a circuit directly connected to the memory cell army 1, MOS transistors constituting the pitch device 2 are also arranged in the same pitch as that of the memory cells. In contrast, MOS transistors constituting the peripheral device 3 are arranged in a larger pitch than that of the MOS transistors constituting the pitch device 2. As a result; a pitch of the MOS transistors constituting the pitch device 2 is smaller than a pitch of the MOS transistors constituting the peripheral device 3.

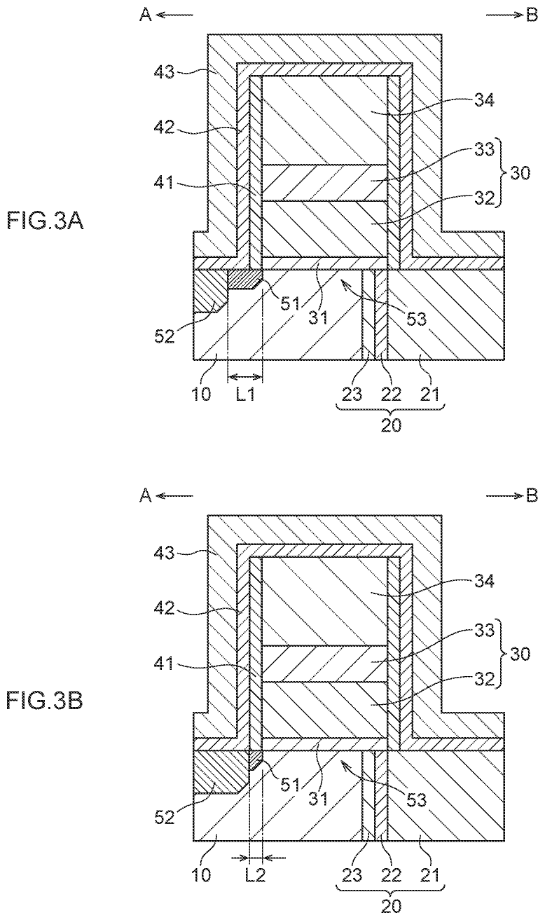

As shown in FIG. 2, each of the MOS transistors included in the pitch device 2 and the peripheral device 3 has a pair of source/drain regions 50, and a gate electrode 30 positioned between the source/drain regions 50 in a planar view. Dummy gate electrodes 30d are placed on the opposite sides of the source/drain regions 50 to the gate electrode 30, respectively. A structure of the MOS transistors constituting the peripheral device 3 is shown in FIG. 3A and a structure of the MOS transistors constituting the pitch device 2 is shown in FIG. 3B. As shown in FIGS. 3A and 3B, each of the MOS transistors included in the pitch device 2 and the peripheral device 3 is formed in an active region 10 including a semiconductor substrate. The active region 10 is surrounded by a STI (Shallow Trench Isolation) region 20. The STI region 20 includes an SOD film 21 including a silicon oxide, a silicon nitride film 22, and a silicon oxide film 23. LDD (Lightly-Doped Drain) regions 51 and source/drain regions 52 are provided in the active region 10. The LDD regions 51 may have an LDD/HALO structure including a HALO region. A region between a pair of the source/drain regions 52 is a channel region 53. The channel region 53 is covered with agate insulating film 31. Agate electrode 30 including a polysilicon film 32 and a tungsten film 33 is provided on the gate insulating film 31. A metal gate may be provided between the gate insulating film 31 and the polysilicon film 32. Atop part of the gate electrode 30 is covered with a gate cap 34 including a silicon nitride. The side surfaces of the gate electrode 30 and the gate cap 34 are covered with aside wall film 41 including a silicon nitride. Further, the side wall film 41 and the gate cap 34 are covered with a liner film 42 including a silicon nitride. The liner film 42 not only covers the side surface and the top surface of the gate electrode 30 but also continuously covers the source/drain regions 52 and the STI region 20. The liner film 42 is covered with a tensile/compressive film 43 including a silicon nitride. The tensile/compressive film 43 is a film that functions as a CESL and plays a role in increasing the carrier mobility by applying physical stress to the channel region 53. As to whether the tensile/compressive film 43 functions as a tensile film or a compressive film can be controlled according to film formation conditions.

In a case where a length of the LDD regions 51 of each of the MOS transistors included in the peripheral device 3 is L1 and a length of the LDD regions 51 of each of the MOS transistors included in the pitch device 2, L1>L2. This enables high-speed switching to be realized in the pitch device 2 and a leakage current to be reduced in the peripheral device 3.

A manufacturing method of the semiconductor device according to the present embodiment is explained next.

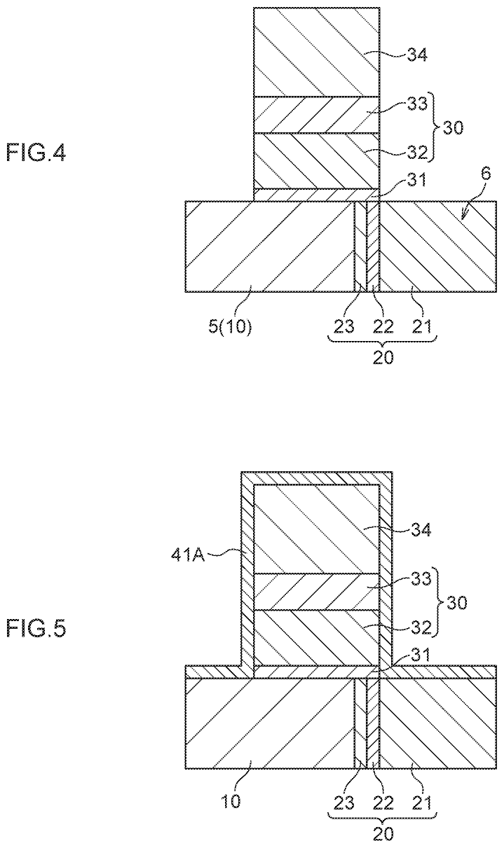

First as shown in FIG. 4, trenches 6 are formed on a semiconductor substrate 5, and inner parts of the trenches 6 are filled with the silicon oxide film 23, the silicon nitride film 22, and the SOD film 21, thereby forming the STI regions 20. Regions respectively surrounded by the STI regions 20 on the semiconductor substrate 5 are the active regions 10. Next, the gate insulating film 31, the polysilicon film 32, the tungsten film 33, and the gate cap 34 are formed in this order on each of the active regions 10, and are subsequently patterned to form the gate electrodes 30. End parts of the gate electrodes 30 are positioned on the STI regions 20. A metal gate may be formed between the gate insulating film 31 and the polysilicon film 32.

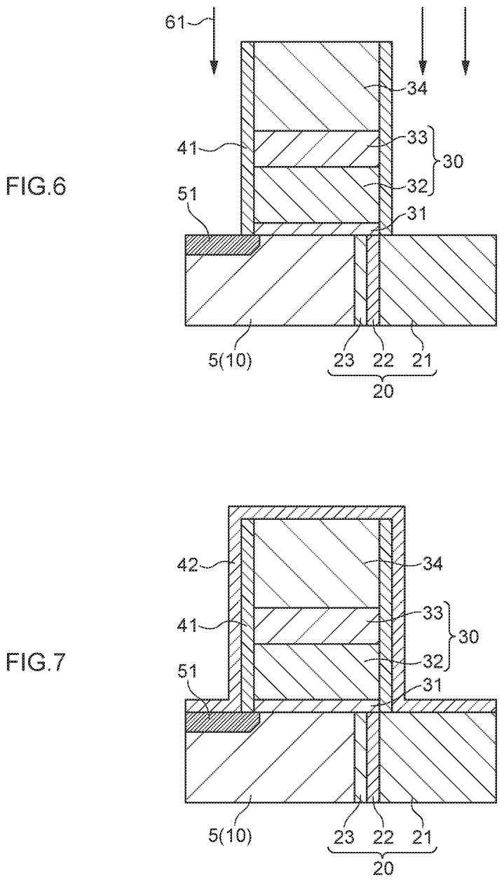

Next, after a silicon nitride film 41A is formed on the entire surface including the side surface and the top surface of each of the gate electrodes 30 as shown in FIG. 5, the silicon nitride film 41A is etched back to form the side wall film 41 as shown in FIG. 6. A dopant 61 is ion-implanted in this state to form the LDD regions 51. The gate electrodes 30 are used as an implant mask to form the LDD regions 51. At this time, HALO regions may be further formed to form an LDD/HALO structure. Next, as shown in FIG. 7, the liner film 42 including a silicon nitride is formed on the entire surface. Accordingly, the side surfaces of the gate electrodes 30 and the gate caps 34 are covered with the liner film 42 with the side wall film 41 interposed therebetween. The active regions 10 and the STI regions 20 are also covered with the liner film 42. The film thickness of the liner film 42 is, for example, 70 Å.

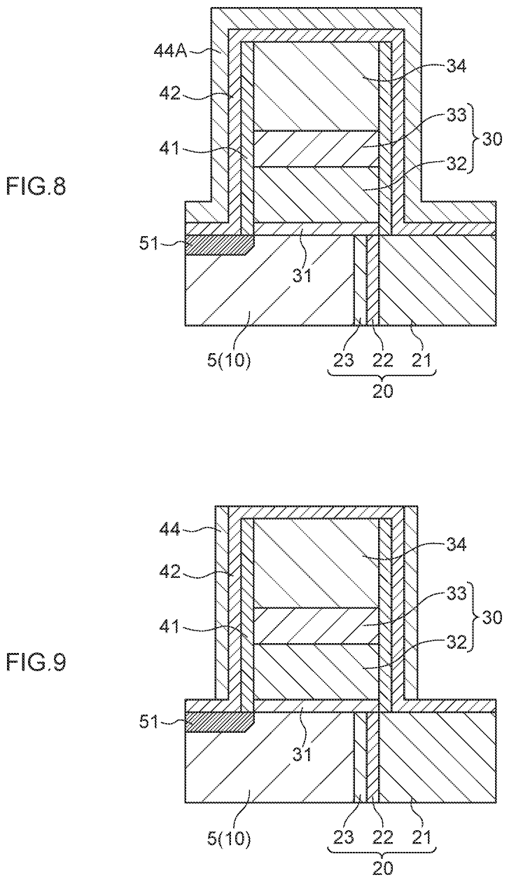

Next, as shown in FIG. 8, a silicon oxide film 44A is formed on the entire surface. The film thickness of the silicon oxide film 44A is, for example, 150 Å. Next, as shown in FIG. 9, the silicon oxide film 44A is etched back to form a side wall film 44. Accordingly, the side surfaces of the gate electrodes 30 and the gate caps 34 are covered with the side wall film 44 with the side wall film 41 and the liner film 42 interposed therebetween.

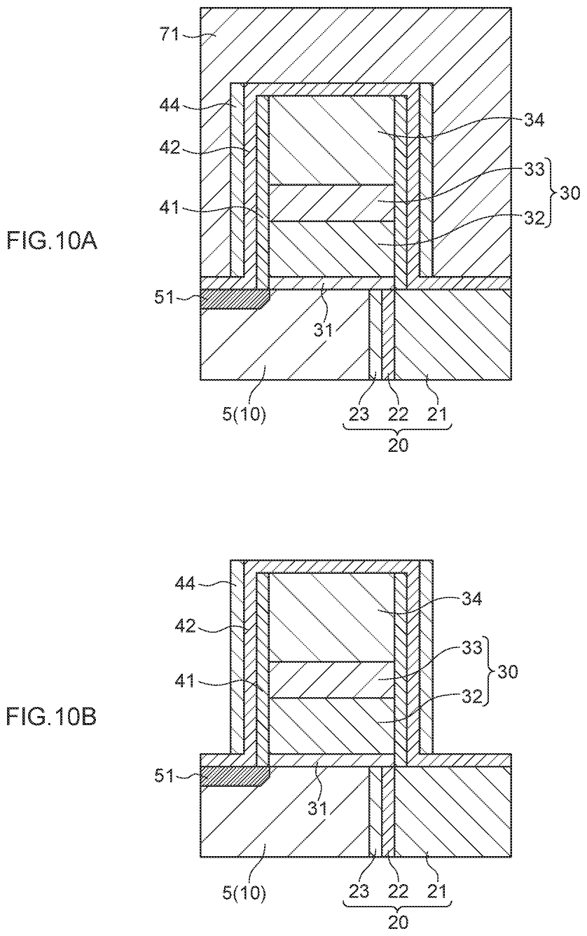

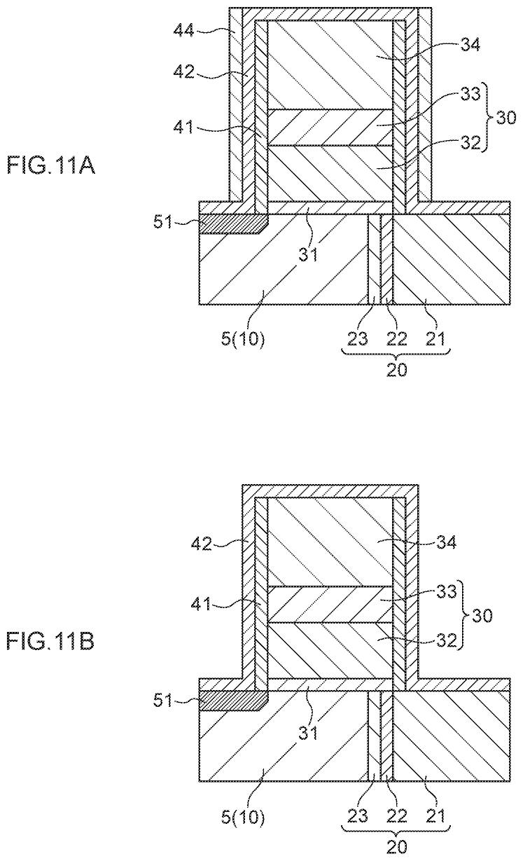

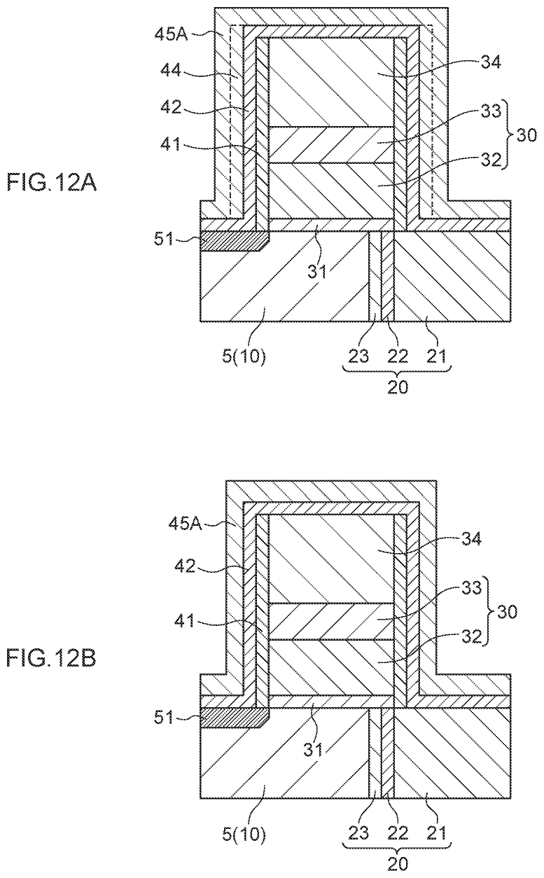

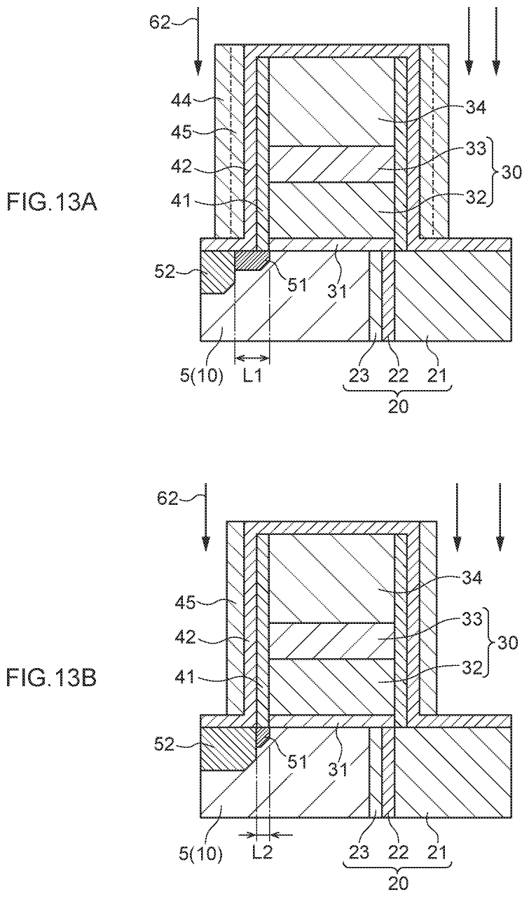

Next, as shown in FIGS. 10A and 10B, the entire surface of the peripheral device 3 is covered with a photomask 71. The photomask 71 covering the pitch device 2 is removed. Etching of the side wall film 44 is performed in this state, thereby selectively removing the side wall film 44 located on the pitch device 2 as shown in FIGS. 11A and 11B. The side wall film 44 located on the peripheral device 3 remains as it is. Next, as shown in FIGS. 12A and 12B, a silicon oxide film 45A is formed on the entire surface. The film thickness of the silicon oxide film 45A is, for example, 150 Å. Next, as shown in FIGS. 13A and 13B, the silicon oxide film 45A is etched back to form the side wall film 45. Accordingly, the side surfaces of the gate electrodes 30 and the gate caps 34 in the peripheral device 3 are covered with two layers of the side wall films 44 and 45 with the side wall film 41 and the liner film 42 interposed therebetween. In contrast, the side surfaces of the gate electrodes 30 and the gate caps 34 in the pitch device 2 are covered with one layer of the side wall film 45 with the side wall film 41 and the liner film 42 interposed therebetween. A dopant 62 is ion-implanted through the liner film 42 in this state, whereby the source/drain regions 52 are formed. This causes the length L1 of the LDD regions 51 in the peripheral device 3 to be long and the length L2 of the LDD regions 51 in the pitch device 2 to be short. The gate electrodes 30, the liner film 42, side wall film 41, side wall film 44 and/or side wall film 45 are used as an implant mask to form the source/drain regions 52. As described above, since the dopant 62 is ion-implanted through the liner film 42 in the present embodiment, the film thickness of the liner film 42 is set to be sufficiently thin.

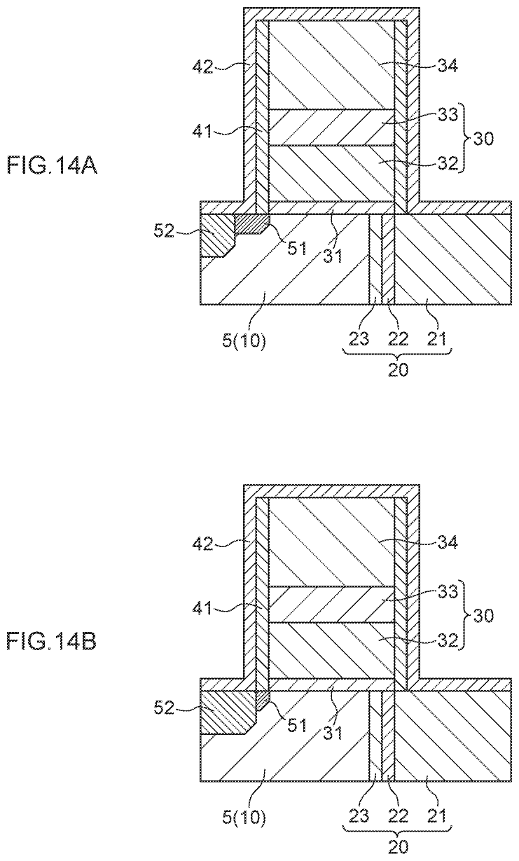

Next, as shown in FIGS. 14A and 14B, the side wall films 44 and 45 are removed by wet etching using hydrofluoric acid. Since the STI regions 20 primarily including a silicon oxide are covered with the liner film 42 at this time, the STI regions 20 are not etched. The tensile/compressive film 43 including a silicon nitride is subsequently formed as shown in FIGS. 3A and 3B, whereby the MOS transistors according to the present embodiment are completed. In this way, the dopant 52 is ion-implanted in a state where the side surfaces of the gate electrodes 30 in the peripheral device 3 are covered with two layers of the side wall films 44 and 45 and the side surfaces of the gate electrodes 30 in the pitch device 2 are covered with one layer of the side wall film 45 in the present embodiment. Therefore, the LDD regions 51 of the peripheral device 3 and the pitch device 2 can be formed to have different lengths. Furthermore, the side wall films 44 and 45 are removed after the source/drain regions 52 are formed and before the tensile/compressive film 43 is formed. Accordingly, the gate electrode interval between adjacent MOS transistors is widened. This enables sufficient stress to be applied to the channel regions because of the tensile/compressive film 43 also in the pitch device 2 in which the MOS transistors are arranged at a high density.

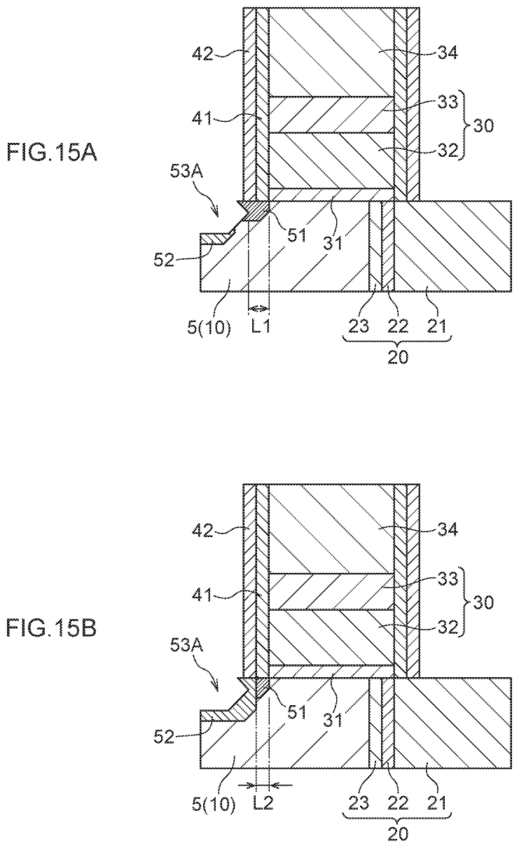

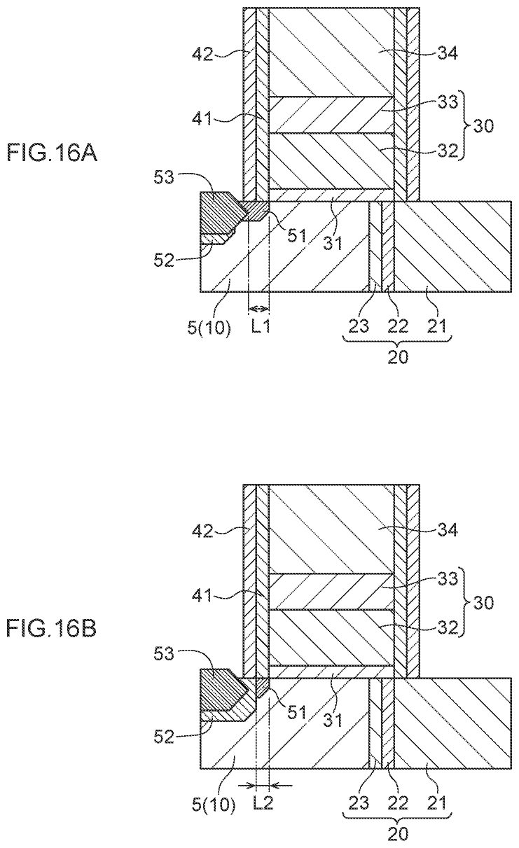

It is alternatively possible to, after removing the side wall films 44 and 45, etch back the liner film 42 as shown in FIGS. 15A and 15B, further etch back the source/drain regions 52 to form recessed regions 53A, and subsequently form an epitaxial layer 53 in the recessed regions 53A as shown in FIGS. 16A and 16B. Also in this case, stress can be applied to the channel regions because of the epitaxial layer 53. Furthermore, since the side wall films 44 and 45 are already removed at the time of formation of the epitaxial layer 53, a reaction gas required for epitaxial growth can be supplied to the recessed regions 53A even when the gate electrode interval between adjacent MOS transistors is narrow.

Although this invention has been disclosed in the context of certain preferred embodiments and examples, it will be understood by those skilled in the art that the inventions extend beyond the specifically disclosed embodiments to other alternative embodiments and/or uses of the inventions and obvious modifications and equivalents thereof. In addition, other modifications which are within the scope of this invention will be readily apparent to those of skill in the art based on this disclosure. It is also contemplated that various combination or sub-combination of the specific features and aspects of the embodiments may be made and still fall within the scope of the inventions. It should be understood that various features and aspects of the disclosed embodiments can be combined with or substituted for one another in order to form varying mode of the disclosed invention. Thus, it is intended that the scope of at least some of the present invention herein disclosed should not be limited by the particular disclosed embodiments described above.

1. An apparatus comprising:
a semiconductor substrate having a plurality of active regions each surrounded by a ST region comprising a first insulating material;
a plurality of MOS transistors formed in the plurality of active regions, each of the plurality of MOS transistors including source/drain regions, a channel region between the source/drain regions, and a gate electrode covering the channel region with a gate insulating film interposed therebetween;
a liner film continuously covering the gate electrode and the source/drain regions of each of the plurality of MOS transistors and the STI region, the liner film comprising a second insulating material different from the first insulating material; and
a tensile/compressive film covering the liner film such that the tensile/compressive film covers the source/drain regions of each of the plurality of MOS transistors and the STI region with the liner film interposed therebetween.

2. The apparatus as claimed in claim 1,
wherein the liner film includes a side wall section covering a side surface of the gate electrode, and
wherein the tensile/compressive film includes a side wall section covering the side wall section ofthelinerfilmwithoutaninsulatingfilmcomprisingthefirstinsulatingmaterialinterposedtherebetween.

3. The apparatus as claimed in claim 1,
wherein the plurality of active regions include first and second active regions,
wherein the each of the plurality of MOS transistors further includes LDD regions between each of the source/drain regions and the channel region, and
wherein the LDD regions of one of the plurality of MOS transistors in the first active region is shorter in length than the LDD regions of another of the plurality of MOS transistors in the second active region.

4. The apparatus as claimed in claim 3,
wherein each of the plurality of the MOS transistors are formed in either one of the first and second active regions, and
wherein a pitch of the gate electrodes of the plurality of MOS transistors in the first active region is smaller than a pitch of the gate electrodes of the plurality of MOS transistors in the second active region.

5. The apparatus as claimed in claim 4, further comprising a memory cell array including a plurality of memory cells arranged in a predetermined pitch,
wherein the pitch of the gate electrodes of the plurality of MOS transistors in the first active region is substantially the same as the predetermined pitch.

6. The apparatus as claimed in claim 1, wherein the first insulating material includes a silicon oxide.

7. The apparatus as claimed in claim 6, wherein the second insulating material includes a silicon nitride.

8. A method comprising:
forming a gate electrode on an active region of a semiconductor substrate surrounded by a STI region;
implanting a first dopant into the active region by using the gate electrode as a mask to form LDD regions;
forming a liner film on top and side surfaces of the gate electrode, the STI region, and the LDD regions;
forming a side wall spacer on the side surfaces of the gate electrode with the liner film interposed therebetween;
implanting, with the liner film covering the STI region and the LDD regions, a second dopant by using the gate electrode, the liner film formed on the side surfaces of the gate electrode, and the side wall spacer as a mask to form source/drain regions; and
removing the side wall spacer.

9. The method as claimed in claim 8, further comprising forming a tensile/compressive film on the liner film after removing the side wall spacer.

10. The method as claimed in claim 8, further comprising:
removing the liner film on the source/drain regions after removing the side wall spacer;
etching-back the source/drain regions; and
forming an epitaxial layer on the source/drain regions.

11. The method as claimed in claim 8, wherein the liner film comprises a different insulating material from the side wall spacer.

12. The method as claimed in claim 11, wherein the liner film comprises a silicon nitride.

13. The method as claimed in claim 12, wherein the side wall spacer comprises a silicon oxide.

14. The method as claimed in claim 13, wherein the STI region comprises a silicon oxide.

15. A method comprising:
forming first and second gate electrodes on first and second active regions of a semiconductor substrate, respectively;
implanting a first dopant into the first and second active regions by using the first and second gate electrodes as a mask to form LDD regions;
forming a liner film on at least a side surface of the first and second gate electrodes;
forming a first side wall spacer on the side surfaces of the first and second gate electrodes with the liner film interposed therebetween;
removing the first side wall spacer on the side surface of the first gate electrode such that the first side wall spacer on the side surface of the second gate electrode remains;
forming a second side wall spacer on the side surface of the first gate electrode with the liner film interposed therebetween and on the side surface of the second gate electrode with the liner film and the first side wall spacer interposed therebetween;
implanting a second dopant by using the first and second gate electrodes, the liner film, the first side wall spacer, and the second side wall spacer as a mask to form source/drain regions; and
removing the first and second side wall spacers.

16. The method as claimed in claim 15, further comprising forming a tensile/compressive film on the liner film after the removing the first and second side wall spacers.

17. The method as claimed in claim 15, further comprising:
removing the liner film on the source/drain regions after the removing the first and second side wall spacers;
etching-back the source/drain regions; and
forming a epitaxial layer on the source/drain regions.

18. The method as claimed in claim 15, wherein the liner film comprises a different insulating material from the first and second side wall spacers.

19. The method as claimed in claim 18, wherein the liner film comprises a silicon nitride.

20. The method as claimed in claim 19, wherein the first and second side wall spacers comprise a silicon oxide.
